(19) United States
(12) Patent Application Publication
(10) Pub. No.: US 2021/0320202 A1
(43) Pub. Date: Oct. 14, 2021

(54) Super Shielded Gate Trench MOSFET Having Superjunction Structure

(71) Applicant: Nami MOS CO., LTD., New Taipei City (TW)

(72) Inventor: Fu-Yuan HSIEH, New Taipei City (TW)

(73) Assignee: Nami MOS CO., LTD., New Taipei City (TW)

(21) Appl. No.: 16/845,112

(22) Filed: Apr. 10, 2020

(51) Int. Cl. H01L 29/78; H01L 29/06; H01L 29/10; H01L 29/40; H01L 21/02; H01L 21/265; H01L 21/765; H01L 29/66

(52) U.S. Cl. CPC H01L 29/7813; H01L 29/0634; H01L 29/1095; H01L 29/407; H01L 29/66734; H01L 21/02532; H01L 21/02579; H01L 21/26513; H01L 21/765; H01L 29/408

(57) ABSTRACT

A trenched semiconductor power device is disclosed comprising a plurality of trenched gates, each including a pair of split gate electrodes and a shielded gate electrode forming an oxide charge balance region between adjacent trenched gates, and junction charge balance region below trench bottom. The trenched semiconductor power device further comprises a super junction structure including a plurality of alternating P and N regions disposed above a substrate forming a junction charge balance region below the oxide charge balance region for breakdown voltage enhancement and on-resistance reductions.

### FIELD OF THE INVENTION

This invention relates generally to semiconductor devices, and more particularly, to a super shielded gate trench MOSFET (Metal Oxide Semiconductor Field Effect Transistor) having oxide charge balance region between adjacent trenched gates and junction charge balance region below trench bottom to maintain a stable high breakdown voltage and lower on-resistance.

### BACKGROUND OF THE INVENTION

Shielded gate trench MOSFETs (SGT) as shown in FIG. 1A have much lower gate charge and on-resistance compared with traditional single gate trench MOSFETs as results of existence of oxide charge balance region in drift region and thick oxide underneath gate electrode. However, an early breakdown always occurs at trench bottom. A degradation of the breakdown voltage is therefore becoming a design and operation limitation.

To improve the early breakdown issue, U.S. Pat. No. 8,159,021 disclosed a SGT MOSFET with double epitaxial layers having two different resistivities as shown in FIG. 1B. The first epitaxial layer (N1 Epi, as shown in FIG. 1B) has a greater resistivity than the second epitaxial layer (N2 Epi), and the trench bottom located in the first epitaxial layer enhances the breakdown voltage. However, on-resistance is higher comparing with single epitaxial layer as result of the first epitaxial layer having higher resistivity than the second epitaxial layer. Therefore, there is still a need in the art of the semiconductor device design and fabrication, particularly for SGT MOSFET design and fabrication, to provide a novel cell structure, device configuration and manufacturing process that making a SGT MOSFET have stable breakdown voltage.

### SUMMARY OF THE INVENTION

This invention disclosed a new SGT MOSFET having, oxide charge balance region between adjacent trenched gates and junction charge balance region below trench bottom to ensure that whole drift region is fully depleted and breakdown occurs at middle of adjacent trenched gates without having early breakdown occurring at trench bottom. Moreover, sensitivity of breakdown voltage on trench bottom oxide thickness and trench depth is thus significantly relaxed or immunized. Avalanche capability is also enhanced.

According to one aspect, the invention features a trenched semiconductor power device comprising a SGT MOSFET formed in an epitaxial layer of a first conductivity type onto a substrate, further a plurality of trenched gates surrounded by source regions of the first conductivity type encompassed in body regions of a second conductivity type near a top surface of the epitaxial layer, wherein each of the trenched gates includes a pair of split gate electrodes and a shielded gate electrode; an oxide charge balance region for lied between adjacent of the trenched gates; a super junction structure comprising a plurality of alternating P and N regions disposed above the substrate and below the oxide charge balance regions.

In another aspect, the present invention features a trenched semiconductor power device further comprising: a first gate insulation layer formed along trench sidewalls of a lower portion of each of the gate trenches; the shielded gate electrode formed within each of the gate trenches and surrounded by the first gate insulation layer in the lower portion of each of the gate trenches; a second gate insulation layer thermal grown at least along trench sidewalls of an upper portion of each of the gate trenches, the second gate insulation layer having a thinner thickness than the first gate insulation layer; a third gate insulation layer formed by fully oxidizing upper portion of the shielded gate electrodes above the first insulation layer during the second insulation layer thermally grown; and the pair of split gate electrodes disposed adjacent to the second gate insulation layer and above the first gate insulation layer in the upper portion of each of the gate trenches, the pair of split gate electrodes are separated from each other by the third gate insulation layer; and the body regions, the shielded gate electrodes and the source regions being shorted to a source metal through a plurality of trenched contacts.

According to another aspect, in some preferred embodiments, the substrate has the first conductivity type and the epitaxial layer comprises a single epitaxial layer having uniform doping concentration. In some other preferred embodiments, the substrate has the first conductivity type and the epitaxial layer comprises a lower epitaxial layer with resistivity R1 and an upper epitaxial layer with resistivity R2, wherein the relationship between R1 and R2 can be R1>R2 or R2>R1. In some other preferred embodiments, the substrate has the first or the second conductivity type and the epitaxial layer comprises a single epitaxial layer having uniform doping concentration with resistivity R. the trenched semiconductor power device further comprises a buffer epitaxial layer of the first conductivity type with resistivity Rn sandwiched between the substrate and said epitaxial layer, wherein R>Rn. In some other preferred embodiments, the substrate has the second conductivity type and the epitaxial layer comprises a lower epitaxial layer with resistivity R1 and an upper epitaxial layer with resistivity R2, the trenched semiconductor power device further comprises a buffer layer of the first conductivity type with resistivity Rn sandwiched between the substrate and the lower epitaxial layer, wherein the relationship between R1, R2 and Rn can be R1>R2>Rn or R2>R1>Rn.

According to another aspect, in some preferred embodiments, the P regions of the super junction structure are mainly disposed below bottoms of the shielded gate electrodes and touch to bottom surface of the epitaxial layer In some other preferred embodiments, the P regions of the super junction structure are mainly disposed below bottoms of the shielded gate electrodes without touching to bottom surface of the epitaxial layer.

According to another aspect, in some preferred embodiments, the substrate has the second conductivity type and the trenched semiconductor power device further comprises: a buffer layer of the first conductivity type formed sandwiched between the substrate and the epitaxial layer; and a plurality of heavily doped regions of the first conductivity type formed in the substrate to form a plurality of alternating P+ and N+ regions.

According to another aspect, in sonic preferred embodiments, the trenched semiconductor power device further comprises a charge storage region of the first conductivity type encompassed in the epitaxial layer and below the body regions, wherein the charge storage region has a higher doping concentration than the epitaxial layer.

According to another aspect, the first conductivity type is N type and the second conductivity tape is P type; or the first conductivity type is P type and the second conductivity type is N type.

According to another aspect, the superjunction structure is formed by using multiple epitaxial growth method or trench refilling P type epitaxial layer method or multiple ion implantation through trench bottom.

The invention also features a method for manufacturing a trench MOSFET comprising the steps of: (a) forming a superjuction structure into an N1 epitaxial layer by either trench filling of P type epitaxial layer or multi-epitaxial growth method in which process of introducing a P type impurity into a certain areas of each epitaxial layer by ion implantation, and the step is performed repeatly; (b) growing another N2 epitaxial layer of a first conductivity type upon the superjunction structure, wherein the epitaxial layer having a lower or higher doping concentration than the N1 epitaxial layer; (c) forming a hard mask such as an oxide onto a top surface of the epitaxial layer for definition of a plurality of gate trenches; (d) forming the plurality of gate trenches, and mesas between two adjacent gate trenches in the epitaxial layer by etching through open regions in the hard mask; (e) forming a thick oxide layer along inner surfaces of the gate trenches by thermal oxide growth or oxide deposition; (f) depositing a first doped poly-silicon layer filling the gate trenches to serve as shielded gate electrodes; (g) etching back the shielded gate electrodes from the top surface of the epitaxial layer; (h) etching back the thick oxide layer from the top surface of the epitaxial layer and an upper portion of the gate trenches; (i) forming a thin oxide layer covering at least along trench sidewalk of an upper portion of each of the gate trenches, the second gate insulation layer having a thinner thickness than said first gate insulation layer; (j) forming a third gate insulation layer by fully oxidizing upper portion of the shielded gate electrode above the first insulation layer during the second insulation layer is thermally grown; (k) depositing a second doped poly-silicon layer filling the upper portion of the gate trenches to serve as split gate electrodes; (l) etching back the split gate electrodes by CMP (Chemical Mechanical Polishing) or plasma etch; (m) carrying out a body implantation of the second conductivity type dopant and a step of body diffusion to form body regions; (n) applying a source mask onto the top surface of the epitaxial layer; and (o) carrying out a source implantation of the first conductivity type dopant and a source diffusion to form source regions.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description to explain the principles of the invention. In the drawings:

FIG. 1A is a cross-sectional view of a SGT MOSFET of prior art.

FIG. 1B is a cross-sectional view of another SGT MOSFET of prior art.

FIG. 2A is a cross-sectional view of a preferred embodiment according to the present invention.

FIG. 2B is a cross-sectional view of another preferred embodiment according to the present invention.

FIG. 3 is a cross-sectional view of another preferred embodiment according to the present invention.

FIG. 4A is a cross-sectional view of another preferred embodiment according to the present invention.

FIG. 4B is a cross-sectional view of another preferred embodiment according to the present invention.

FIG. 5 is a cross-sectional view of another preferred embodiment according to the present invention.

FIG. 6A is a cross-sectional view of another preferred embodiment according to the present invention.

FIG. 6B is a cross-sectional view of another preferred embodiment according to the present invention.

FIG. 7A is a cross-sectional view of another preferred embodiment according to the present invention.

FIG. 7B is a cross-sectional view of another preferred embodiment according to the present invention.

FIG. 8A is a cross-sectional view of another preferred embodiment according to the present invention.

FIG. 8B is a cross-sectional view of another preferred embodiment according to the present invention.

FIGS. 9A-9F are a serial of side cross-sectional views for showing the processing steps for fabricating the trench MOSFET of FIG. 4A.

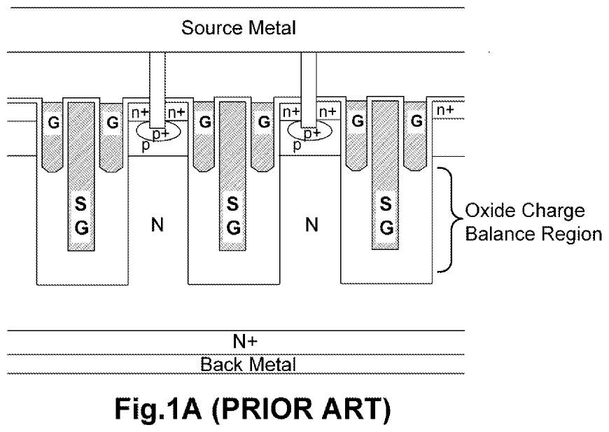

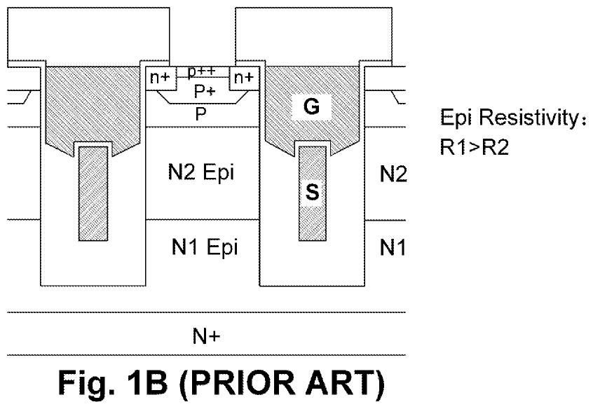

### DETAILED DESCRIPTION OF THE EMBODIMENTS

In the following Detailed Description, reference is made to the accompanying drawings, .which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

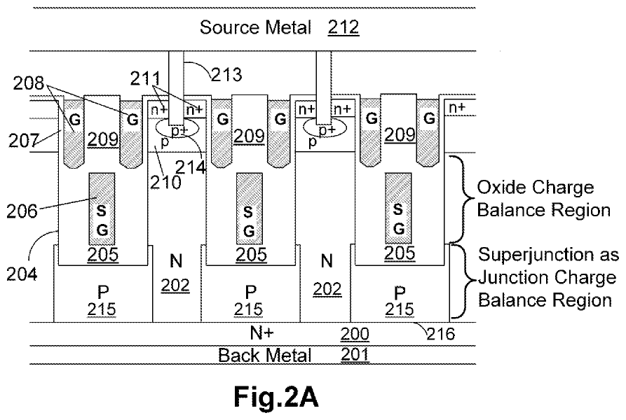

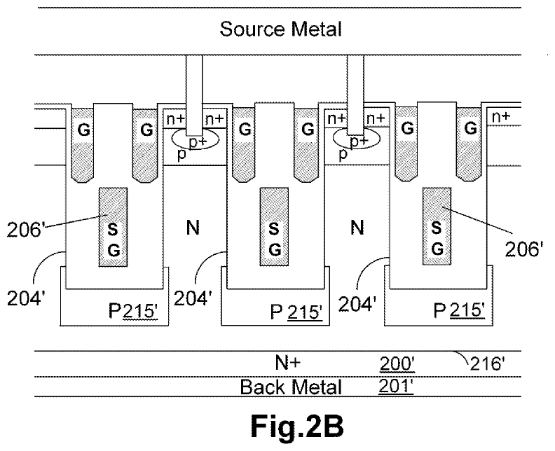

Please refer to FIG. 2A for a preferred embodiment of this invention. A trenched semiconductor power device comprises an N-channel SGT MOSFET formed in an N type epitaxial layer 202 onto an N+ substrate 200 coated with a back metal 201 of Ti/Ni/Ag on rear side as a drain metal. The SGT MOSFET further comprises a plurality of trenched gates 204 extending from a top surface of the N epitaxial layer 202 and extending downward into the N epitaxial layer 202 in an active area, wherein trench bottoms of the gate trenches 204 are above a common interface between the N+ substrate 200 and the N epitaxial layer 202, inside each of the trenched gates 204 a shielded gate electrode (SG, as illustrated) 206 is disposed in the lower portion and a pair of split gate electrode 208 is disposed in the upper portion, the shielded gate electrode 206 is insulated from the adjacent epitaxial layer by a first insulating film 205 and the pair of split gate electrodes 208 is insulated from the adjacent epitaxial layer by a second insulating film 207, wherein the second insulating film 207 has a thinner thickness than the first insulating film 205, meanwhile, the pair of split gate electrodes is disposed adjacent to the second gate insulation layer 207 and above the first gate insulation layer 205 in the upper portion of the gate trenches, and are separated from each other by the third gate insulation layer 209. Between every two adjacent trenched gates 204, a P body region with n+ source regions 211 thereon is extending near top surface of the upper N epitaxial layer 202 and surrounding the pair of split gate electrodes 208 padded by the second insulating film 207. The P body regions 210, the n+ source regions 211 and the shielded gate electrodes 206 are further shorted to a source metal 212 through a plurality of trenched contacts 213 filled with contact plugs and surrounded by p+ heavily doped regions 214 around bottoms underneath the n+ source regions 211. According to the invention, an oxide charge balance region is therefore formed between adjacent of the trenched gates 204, meanwhile, around bottoms of the trenched gates 204, P regions 215 are introduced into the lower N epitaxial layer 202 to form a superjunction to act as junction charge balance region, comprising a plurality of alternating P regions 215 and N regions 202 above the N+ substrate 200 and below the oxide charge balance region to ensure that whole drift region is fully depleted and breakdown occurs at middle of adjacent trenched gates without having early breakdown voltage occurring at trench bottom, and at the same time, to significantly relax the sensitivity of breakdown voltage on trench bottom thickness and trench depth. According to this embodiment, the P regions 215 are mainly disposed below bottoms of the shielded gate electrodes 206 in the trenched gates 204 and touch to bottom surface 216 of the epitaxial layer. The P regions 215 can be easily formed by multiple ion-implanation of boron through bottom of the trench gates 204 with various implantation energies.

Please refer to FIG. 2B for another preferred embodiment of the present invention, the N-channel trenched semiconductor power device has a similar structure to FIG. 2A, except that, in FIG. 2B, in the super junction structure above the N+ substrate 200′, the P regions 215′ are mainly disposed below bottoms of the shielded gate electrodes 206′ in the trenched gates 204′ but without touching to bottom surface 216′ of the epitaxial layer

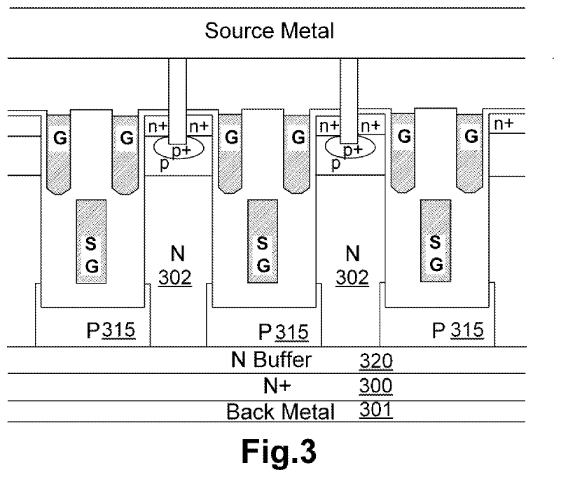

Please refer to FIG. 3 for another preferred embodiment of the present invention, the N-channel trenched semiconductor power device has a similar structure to FIG. 2A, except that, in FIG. 3, the invention further comprises a N buffer layer 320 with resistivity Rn sandwiched between the N+ substrate 300 and the N epitaxial layer 302, the epitaxial layer comprises a single epitaxial layer having uniform doping concentration with resistivity R, wherein R>Rn.

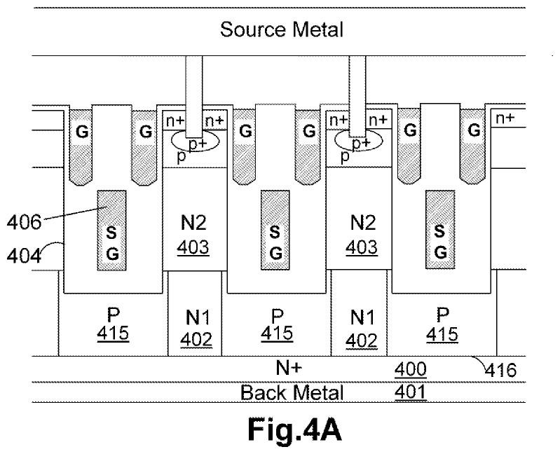

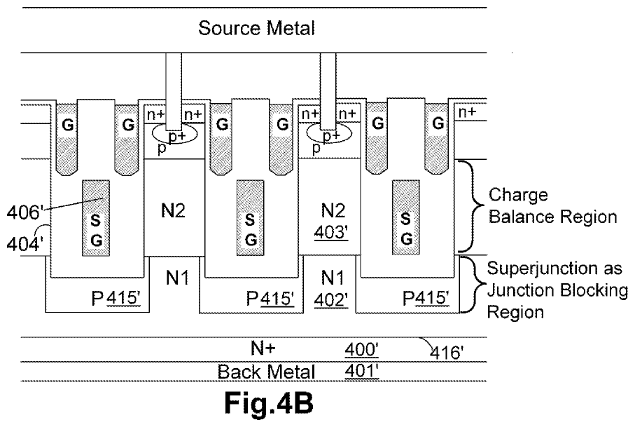

Please refer to FIG. 4A for another preferred embodiment of the present invention, the N-channel trenched semiconductor power device has a similar structure to FIG. 2A, except that, the epitaxial layer in FIG. 4A comprises a lower N1 epitaxial layer 402 with resistivity R1 and an upper N2 epitaxial layer 403 with resistivity R2, wherein R1>R2>Rn (or the relationship can be R2>R1>Rn). The super junction region comprises a plurality of alternating P regions 415 and the lower N1 epitaxial layer 402, wherein the P regions 415 are mainly disposed below bottoms of the shielded gate electrodes 406 in the trenched gates 404 and touch to bottom surface 416 of the epitaxial layer

Please refer to FIG. 4B for another preferred embodiment of the present invention, the N-channel trenched semiconductor power device has a similar structure to FIG. 4A, except that, in FIG. 4B, in the super junction structure above the N+ substrate 400′, the P regions 415′ are mainly disposed below bottoms of the shielded gate electrodes 406′ in the trenched gates 404′, but without touching to bottom surface 416′ of the epitaxial layer.

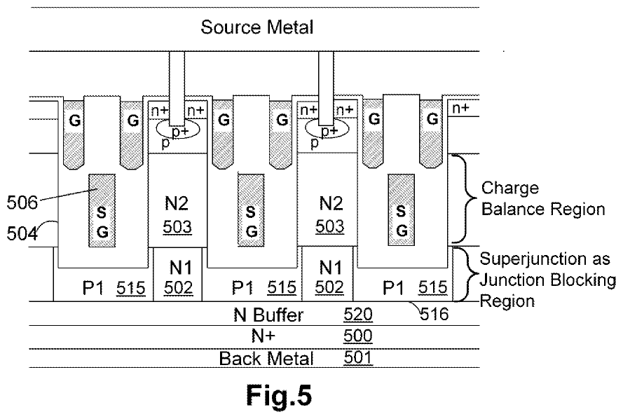

Please refer to FIG. 5 for another preferred embodiment of the present invention, the N-channel trenched semiconductor power device is formed onto a N+ substrate 500 and further comprises a N buffer layer 520 with resistivity Rn between the N+ substrate 500 and the epitaxial layer. Similar to FIG. 4A, the epitaxial layer in FIG. 5 comprises a lower N1 epitaxial layer 502 with resistivity R1 and an upper N2 epitaxial layer 503 with resistivity R2, wherein R1>R2>Rn (or the relationship can be R2>R1>Rn). The super junction region comprises a plurality of alternating P1 regions 515 and the lower N1 epitaxial layer 502 to act as junction blocking region, wherein the P1 regions 515 are mainly disposed below bottoms of the shielded gate electrodes 505 in the trenched gates 504 and touch to bottom surface 516 of the epitaxial

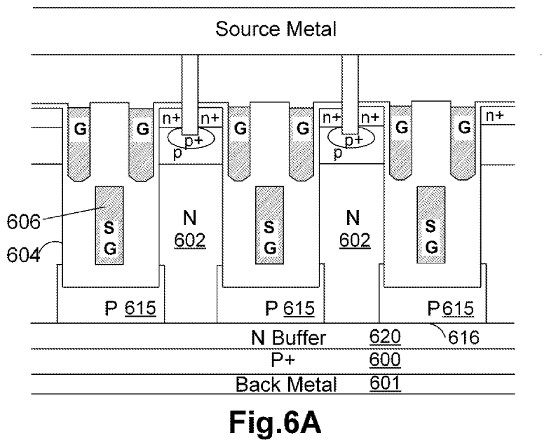

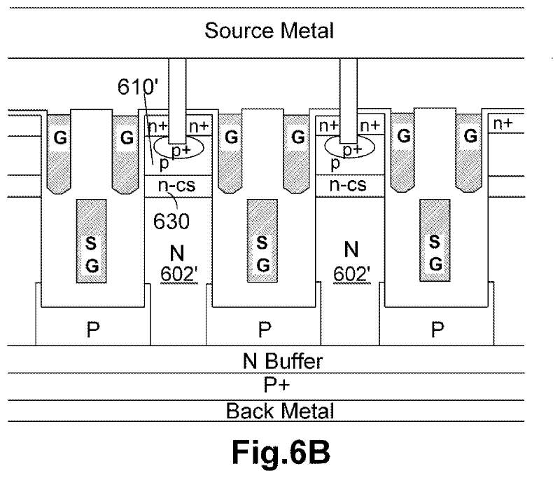

Please refer to FIG. 6A for another preferred embodiment of the present invention, the N-channel trenched semiconductor power device representing an IGBT (Insulating Gate Bipolar Transistor) device has a similar structure to FIG. 3, except that, in FIG. 6A, the IGBT is formed onto a P+ substrate 600 and further comprises a N buffer layer 620 with resistivity Rn between the P+ substrate 600 and the N epitaxial layer 602, the epitaxial layer comprises a single epitaxial layer having uniform doping concentration with resistivity R, wherein R>Rn.

Please refer to FIG. 6B for another preferred embodiment of the present invention, the N-channel trenched semiconductor power device representing an IGBT (Insulating Gate Bipolar Transistor) device has a similar structure to FIG. 6A, except that, the structure in FIG. 6B further comprises a plurality of N type charge storage region (n-cs, as illustrated) 630 encompassed in the upper N epitaxial layer 602′ and below the P body regions 610′, wherein the N type charge storage regions 630 has a higher doping concentration than the r N epitaxial layer 602′.

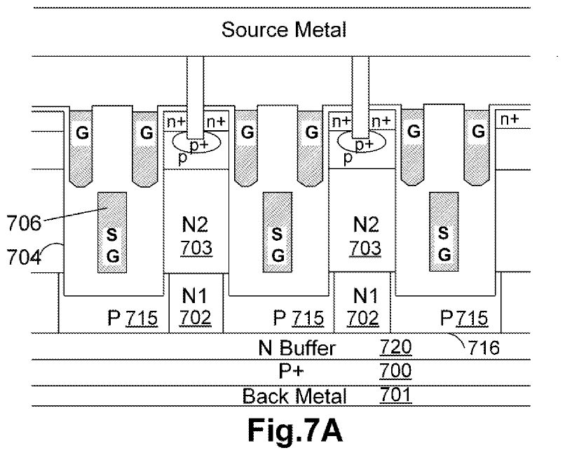

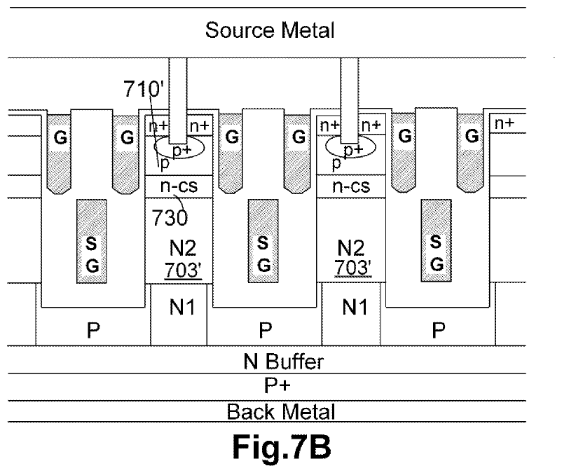

Please refer to FIG. 7A for another preferred embodiment of the present invention, the N-channel trenched semiconductor power device representing an IGBT (Insulating Gate Bipolar Transistor) device has a similar structure to FIG. 6A, except that, the epitaxial layer in FIG. 7A comprises a lower N1 epitaxial layer 702 with resistivity R1 and an upper N2 epitaxial layer 703 with resistivity R2, wherein R1>R2>Rn (or the relationship can be R2>R1>Rn). The super junction region comprises a plurality of alternating, P regions 715 and the lower N1 epitaxial layer 702, wherein the P regions 715 are mainly disposed below bottoms of the shielded gate electrodes 706 in the trenched gates 704 and touch to bottom surface 716 of the epitaxial layer.

Please refer to FIG. 7B for another preferred embodiment of the present invention, the N-channel trenched semiconductor power device representing an IGBT (Insulating Gate Bipolar Transistor) device has a similar structure to FIG. 7A, except that, the structure in FIG. 7B further comprises a plurality of N type charge storage region (n-cs, as illustrated) 730 encompassed in the upper N2 epitaxial layer 703′ and below the P body regions 710′, wherein the N type charge storage regions 730 has a higher doping concentration than the upper N2 epitaxial layer 703′.

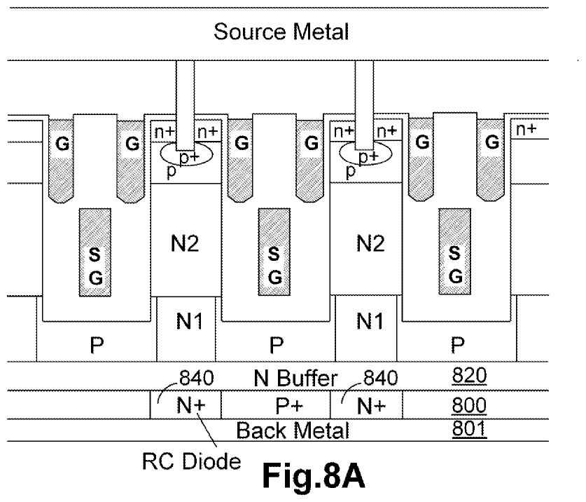

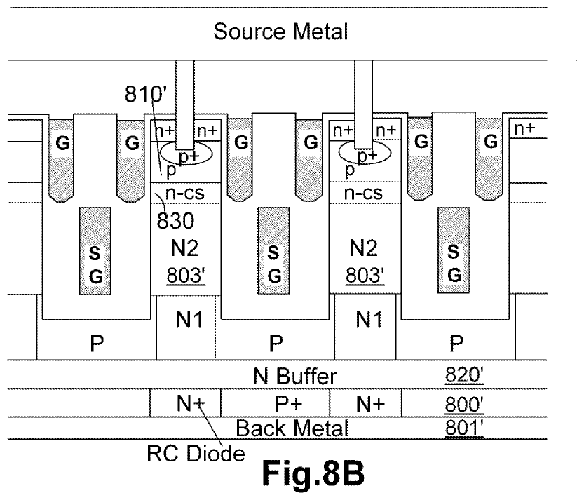

Please refer to FIG. 8A for another preferred embodiment of the present invention, the N-channel trenched semiconductor power device has a similar structure to FIG. 7A, except that, the IGBT in FIG. 8A further comprise a plurality of heavily doped N+ regions 840 formed in the P+ substrate 800 to form a plurality of alternating P+ and N+ regions to serve as integrated reverse conducting, diode (RC Diode, as illustrated).

Please refer to FIG. 8B for another preferred embodiment of the present invention, the N-channel trenched semiconductor power device has a similar structure to FIG. 8A, except that, the structure in FIG. 8B further comprises a plurality of N type charge storage region (n-cs, as illustrated) 830 encompassed in the upper N2 epitaxial layer 803′ and below the P body regions 810′, wherein the N type charge storage regions 830 has a higher doping concentration than the upper N2 epitaxial layer 803′.

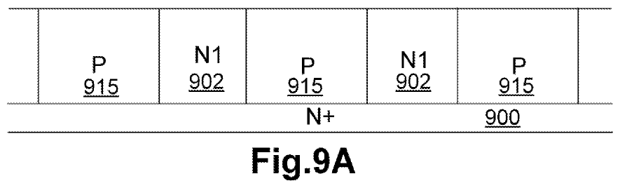

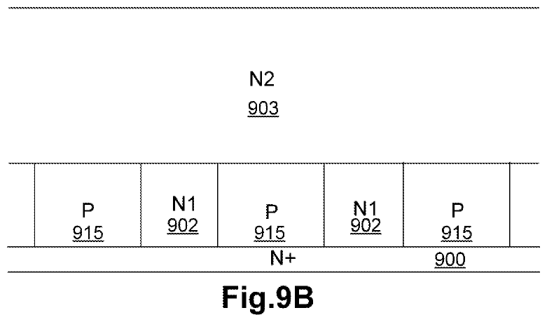

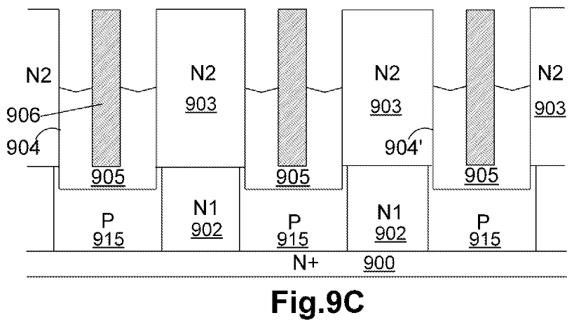

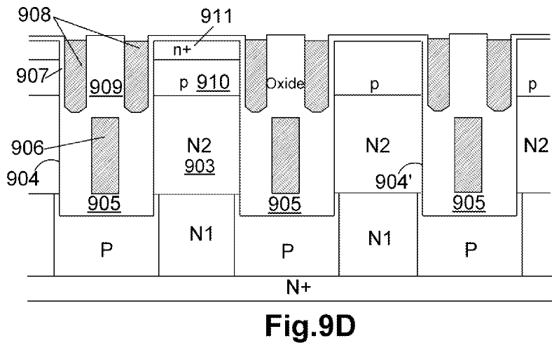

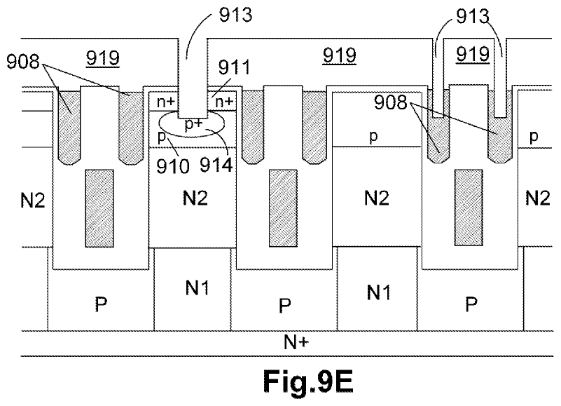

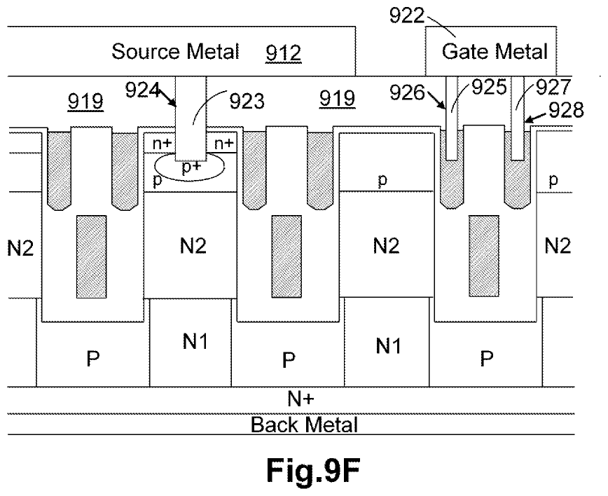

FIGS. 9A-9F are a serial of exemplary steps that are performed to form the inventive trench MOSFET of FIG. 4A. In FIG. 9A, an N1 epitaxial layer 902 is grown on an N+ substrate 900, then the superjunction structure is formed into the N1 epitaxial layer 902 by either trench filling of P type epitaxy layer 915 or by multi-epitaxial growth method: P type impurity was introduced into regions 915 by ion implantation, and above procedure is repeated until a certain drift layer thickness is achieved, and then lastly, thermal diffusion is used to fabricate consecutive n-type and p-type regions, which is also called superjunction structure.

In FIG. 9B, an N2 epitaxial layer 903 is grown on top surface of the superjunction structure.

In FIG. 9C, a hard mask (not shown) such as an oxide layer is formed onto a top surface of the N2 epitaxial layer 903 for definition of areas for a plurality of gate trenches. Then, after dry oxide etch and dry silicon etch, a plurality of gate trenches 904 are etched penetrating through open regions in the hard mask, the N2 epitaxial layer 903, and extending into the P regions 915, not reaching the top surface of N+ substrate 900. Meanwhile, at least a gate contact trench 904′ is formed in the same steps, which is also starting from the top surface of the N2 epitaxial layer 903 and extending into the P regions 915, not reaching the top surface of N+ substrate 900. Mesas are formed between every two adjacent gate trenches 904 and the gate contact trench 904′ in the N2 epitaxial layer 903. Then, a sacrificial oxide layer (not shown is first grown and then removed to eliminate the plasma damage after forming the gate trenches 904 and the gate contact trench 904′. The hard mask is removed, Then, a first gate insulation layer 905 comprising a thick oxide layer is formed lining the inner surface of the gate trenches by thermal oxide growth or thick oxide deposition. Then, a first doped poly-silicon layer is deposited onto the first gate insulation layer 905 to fill the gate trenches 904 and the gate contact trench 904′, and is then etched back from the top surface of the N2 epitaxial layer 903 to serve as the shielded gate electrode 906. Next, the first gate insulation layer 905 is etched back from top surface of the epitaxial layer and an upper portion of the gate trenches 904 and the gate contact trench 904′.

In FIG. 9D, a second gate insulation layer 907 comprising a thin oxide layer is grown along upper inner surfaces of the gate trenches 904 and the gate contact trench 904′, covering a top surface of the first gate insulation layer 905 and the shielded gate electrode 906. A third gate insulation layer 909 is formed by fully oxidizing upper portion of said shielded gate electrode above the first insulation layer 905 during the second insulation layer is thermally grown. After that, a second doped poly-silicon layer is deposited filling the upper portion of the gate trenches 904 and the gate contact trench 904′, and is then etched back by CMP (Chemical Mechanical Polishing) or Plasma Etch to serve as split gate electrodes 908. Each of the split gate electrodes 908 is symmetrically disposed in the middle between the shielded gate electrode 906 and adjacent to trench sidewall in the gate trenches 904 and the gate contact trench 904′. Then, a body implantation of p conductivity type dopant is carried out over entire top surface to form p body regions 910 between every two adjacent gate trenches 904 and the gate contact trench 904′. After applying a source mask (not shown) onto the top surface of the epitaxial layer, a source implantation of n conductivity type dopant and a diffusion step are successively carried out to form an n+ source region 911 near a top surface of the p body regions 910 between two adjacent gate trenches 904 in an active area.

In FIG. 9E, another oxide layer is deposited onto the top surface of the epitaxial layer to serve as a contact interlayer 919. Then, after applying a contact mask (not shown) onto the contact interlayer 919, a plurality of trenched contacts 913 are formed by successively dry oxide etch and dry silicon etch penetrating through the contact interlayer 919, and extending into the p body regions 910 for trenched source-body contacts, and into the split gate electrodes 908 for trenched gate contacts, respectively. Next, a BF2 Ion Implantation is performed to form a p+ body contact doped region 914 within the p body regions 910 and surrounding at least bottom of the trenched source body-contacts penetrating through the n+ source region 911 and extending into the p body region 910.

In FIG. 9F, a harrier metal layer of Ti/TiN or Co/TiN or Ta/TiN is deposited on sidewalls and bottoms of all the trenched contacts 913 followed by a step of RTA process for silicide formation. Then, a tungsten material layer is deposited onto the barrier layer, wherein the tungsten material layer and the barrier layer are then etched back to form: contact metal plug 923 for the trenched source-body contacts 924; and contact metal plugs (925 and 927) for the trenched gate contacts (926 and 928). Then, a metal layer of Al alloys or Cu padded by a resistance-reduction layer Ti or Ti/TiN underneath is deposited onto the contact interlayer 919 and followed by a metal etching process by employing a metal mask (not shown) to be patterned as a source metal 912 and a gate metal 922.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly; it is intended that the appended claims be interpreted as covering all alternations and modifications as fall within the true spirit and scope of the invention.

What is claimed is:

1. A trenched semiconductor power device comprising an SGT MOSFET formed in an epitaxial layer of a first conductivity type onto a substrate, further comprising:
a plurality of trenched gates surrounded by source regions of said first conductivity type encompassed in body regions of a second conductivity type near a top surface of said epitaxial layer, each of said trenched gates including a pair of split gate electrodes and a shielded gate electrode;
an oxide charge balance region formed between adjacent of said trenched gates;
a superjunction structure comprising a plurality of alternating P and N regions disposed above said substrate and below said oxide charge balance region;
said trenched semiconductor power device further comprising:
a first gate insulation layer formed along trench sidewalls of a lower portion of each of said gate trenches;
said shielded gate electrode formed within each of said gate trenches and surrounded by said first gate insulation layer in said lower portion of each of said gate trenches;
a second gate insulation layer thermal grown at least along trench sidewalls of an upper portion of each of said gate trenches, said second gate insulation layer having a thinner thickness than said first gate insulation layer;
a third gate insulation layer formed by fully oxidizing upper portion of said shielded gate electrode above said first insulation layer during said second insulation layer thermally grown; and
said pair of split gate electrodes disposed adjacent to said second gate insulation layer and above said first gate insulation layer in said upper portion of each of said gate trenches, said pair of split gate electrodes are separated from each other by said third gate insulation layer; and
said body regions, said shielded gate electrodes and said source regions being shorted to a source metal through a plurality of trenched contacts.

2. The trenched semiconductor power device of claim 1, wherein said substrate has said first conductivity type and said epitaxial layer comprises a single epitaxial layer having uniform doping concentration.

3. The trenched semiconductor power device of claim 1, wherein said substrate has said first conductivity type and said epitaxial layer comprises a lower epitaxial layer with resistivity R1 and an upper epitaxial layer with resistivity R2, wherein R1>R2.

4. The trenched semiconductor power device of claim 1, wherein said substrate has said first conductivity type and said epitaxial layer comprises a lower epitaxial layer with resistivity R1 and an upper epitaxial layer with resistivity R2, wherein R1<R2.

5. The trenched semiconductor power device of claim 1, wherein said substrate has said first conductivity type and said epitaxial layer comprises a single epitaxial layer having uniform doping concentration with resistivity R, said trenched semiconductor power device further comprises a buffer epitaxial layer of said first conductivity type with resistivity Rn sandwiched between said substrate and said epitaxial layer, wherein R>Rn.

6. The trenched semiconductor power device of claim 1, wherein said substrate has said second conductivity type and said epitaxial layer comprises a single epitaxial layer having uniform doping concentration with resistivity R, said trenched semiconductor power device further comprises a buffer epitaxial layer of said first conductivity type with resistivity Rn sandwiched between said substrate and said epitaxial layer, wherein R>Rn.

7. The trenched semiconductor power device of claim 1, wherein said substrate has said second conductivity type and said epitaxial layer comprises a lower epitaxial layer with resistivity R1 and an upper epitaxial layer with resistivity R2, the shielded gate trench MOSFET further comprises a buffer epitaxial layer of said first conductivity type with resistivity Rn sandwiched between said substrate and said lower epitaxial layer, wherein R1>R2>Rn.

8. The trenched semiconductor power device of claim 1, wherein said substrate has said second conductivity type and said epitaxial layer comprises a lower epitaxial layer with resistivity R1 and an upper epitaxial layer with resistivity R2, the shielded gate trench MOSFET further comprises a buffer epitaxial layer of said first conductivity type with resistivity Rn sandwiched between said substrate and said lower epitaxial layer, wherein R2>R1>Rn.

9. The trenched semiconductor power device of claim 1, wherein said P regions of said super junction structure mainly dispose below bottoms of said shielded gate electrodes and touch to bottom surface of said epitaxial layer.

10. The trenched semiconductor power device of claim 1, wherein said P regions of said super junction structure mainly dispose below bottoms of said shielded gate electrodes without touching to bottom surface of said epitaxial layer.

11. The trenched semiconductor power device of claim 1, wherein said substrate has said second conductivity type, said trenched semiconductor power device further comprises:
a buffer layer of said first conductivity type formed sandwiched between said substrate and said epitaxial layer a plurality of heavily doped regions of said first conductivity type in said substrate to form a plurality of alternating P+ and N+ regions in said substrate.

12. The trenched semiconductor power device of claim 1 further comprises a charge storage region of said first conductivity type encompassed in said epitaxial layer and below said body region, wherein said charge storage region has a higher doping concentration than said epitaxial layer.

13. The trenched semiconductor power device of claim 1, wherein said first conductivity type is N type and said second conductivity type is P type.

14. The trenched semiconductor power device of claim 1, wherein said first conductivity type is P type and said second conductivity type is N type.

15. The trenched semiconductor power device of claim 1, wherein said superjunction structure is formed by using multiple epitaxial growth method in which the process of introducing a P type impurity into a certain areas of each epitaxial layer by ion implantation, and the step is performed repeatly.

16. The trenched semiconductor power device of claim 1, wherein said superjunction structure is formed by trench refilling P type epitaxial layer method.

17. The trenched semiconductor power device of claim 1, wherein said superjunction structure is formed by multiple ion implantation of boron through bottom of said trench gates with various implantation energies.
